(19) United States
(12) Patent Application Publication
(10) Pub. No.: US 2026/0213113 A1
(43) Pub. Date: Jul. 23, 2026

(54) MULTI-CHARGED PARTICLE BEAM IRRADIATION APPARATUS AND MULTI-CHARGED PARTICLE BEAM IRRADIATION METHOD

(71) Applicant: NuFlare Technology, Inc., Yokohama-shi (JP)

(72) Inventors: Takanao TOUYA, Kawasaki-shi (JP); Hirofumi MORITA, Setagaya-ku (JP)

(73) Assignee: NuFlare Technology, Inc., Yokohama-shi (JP)

(21) Appl. No.: 19/400,365

(22) Filed: Nov. 25, 2025

(30) Foreign Application Priority Data
Jan. 17, 2025 (JP) 2025-007036

(51) Int. Cl. H01J 37/04; H01J 37/147; H01J 37/317

(52) U.S. Cl. CPC H01J 37/045; H01J 37/1475; H01J 37/1477; H01J 37/3177; H01J 2237/0435

(57) ABSTRACT

In one embodiment, a multi-charged particle beam irradiation apparatus includes a blanking aperture array substrate having a plurality of blankers that perform blanking deflection on each beam of the multi-beam, an illumination lens that forms a crossover by focusing the multi-beam which passes through the blanking aperture array substrate, a stopping aperture substrate disposed at a position of the crossover and configured to block a beam which is deflected to be in a beam-OFF state, a stage on which a substrate to be irradiated with a beam passing through the stopping aperture substrate is placed, an electrostatic deflector disposed in proximity to the stopping aperture substrate, between the blanking aperture array substrate and the stopping aperture substrate, and a voltage control circuit configured to form an electric field perpendicular to a trajectory central axis of the multi-beam by applying a predetermined voltage to the electrostatic deflector.

### CROSS REFERENCE TO RELATED APPLICATION

This application is based upon and claims benefit of priority from the Japanese Patent Application No. 2025-7036, filed on Jan. 17, 2025, the entire contents of which are incorporated herein by reference.

### FIELD

The present invention relates to a multi-charged particle beam irradiation apparatus and a multi-charged particle beam irradiation method.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. High-precision original patterns are written by an electron beam writing apparatus, and so-called electron beam lithography technique is used.

Some writing apparatuses use a multi-beam, for example. As compared to when writing is performed with a single electron beam, use of a multi-beam allows many beams to be emitted at a time, thus the throughput can be significantly improved. In a multi-beam writing apparatus, for example, an electron beam emitted from an electron source is passed through a shaping aperture array substrate having multiple openings to form a multi-beam, and each beam is individually blanking-controlled by a blanking aperture array substrate. Off-beams deflected for blanking by the blanking aperture array substrate are blocked by a stopping aperture substrate, while on-beams that are not deflected pass through an opening of the stopping aperture substrate and are irradiated onto desired positions on a sample.

When the off-beams deflected for blanking are blocked by the stopping aperture substrate, a large number of secondary electrons are emitted from the stopping aperture substrate. Electron clouds of the secondary electrons are formed near the on-beams and within an expanded beam region, and the electric field generated by the electron clouds deflects the on-beams, causing the irradiation positions on the sample to shift and become unstable. In order to reduce the influence of the secondary electrons on the on-beams, materials that emit a small amount of secondary electrons have been used for the stopping aperture substrate.

However, there is a limit in reduction of the secondary electrons emitted from the stopping aperture substrate. Also, due to deterioration of the material for the stopping aperture substrate over time, the secondary electron emission rate varies with time. When the beam current is increased to improve the throughput, the emission amount of secondary electrons increases in proportion to the beam current, thus the effect of the electric field of secondary electrons on the beams (the on-beams) is increased.

### BRIEF DESCRIPTION OF THE DRAWINGS

FIG. 1 is a schematic configuration view of a writing apparatus according to an embodiment of the present invention.

FIG. 2 is a plan view of a shaping aperture array substrate.

FIG. 3 is a schematic view of secondary electrons which reach the electrode of an electrostatic deflector.

FIGS. 4A, 4B, 4C, 4D and 4E each illustrate a configuration example of an electrostatic deflector.

FIG. 5 is a view for explaining parameters of an electrostatic deflector.

FIG. 6 is a view illustrating a magnetic field deflector that generates a magnetic field perpendicular to a deflection electric field.

FIG. 7 is a plan view illustrating an example of an arrangement of a saddle coil.

FIG. 8 is a plan view illustrating an example of an arrangement of a toroidal coil.

FIG. 9 is a schematic configuration view of a writing apparatus according to another embodiment.

### DETAILED DESCRIPTION

In one embodiment, a multi-charged particle beam irradiation apparatus includes a charged particle source that emits a charged particle beam, a shaping aperture array substrate having a plurality of openings through which the charged particle beam passes to form a multi-beam, a blanking aperture array substrate having a plurality of blankers that perform blanking deflection on each beam of the multi-beam, an illumination lens that forms a crossover by focusing the multi-beam which passes through the blanking aperture array substrate, a stopping aperture substrate disposed at a position of the crossover and configured to block a beam which is deflected to be in a beam-OFF state by the plurality of blankers, a stage on which a substrate to be irradiated with a beam passing through the stopping aperture substrate is placed, an electrostatic deflector disposed in proximity to the stopping aperture substrate, between the blanking aperture array substrate and the stopping aperture substrate, and a voltage control circuit configured to form an electric field perpendicular to a trajectory central axis of the multi-beam by applying a predetermined voltage to the electrostatic deflector.

Hereinafter, an embodiment of the present invention will be described based on the drawings. In the present embodiment, a configuration using an electron beam as an example of a charged particle beam will be described. The charged particle beam is not limited to an electron beam, and may be a beam using a charged particle beam, such as an ion beam. In the present embodiment, a multi-beam writing apparatus using multi-electron beams will be described as an example of a multi charged-particle beam irradiation apparatus. However, the multi-charged particle beam irradiation apparatus is not limited to the multi-beam writing apparatus, and the embodiment may be applied to a multi-beam inspection apparatus.

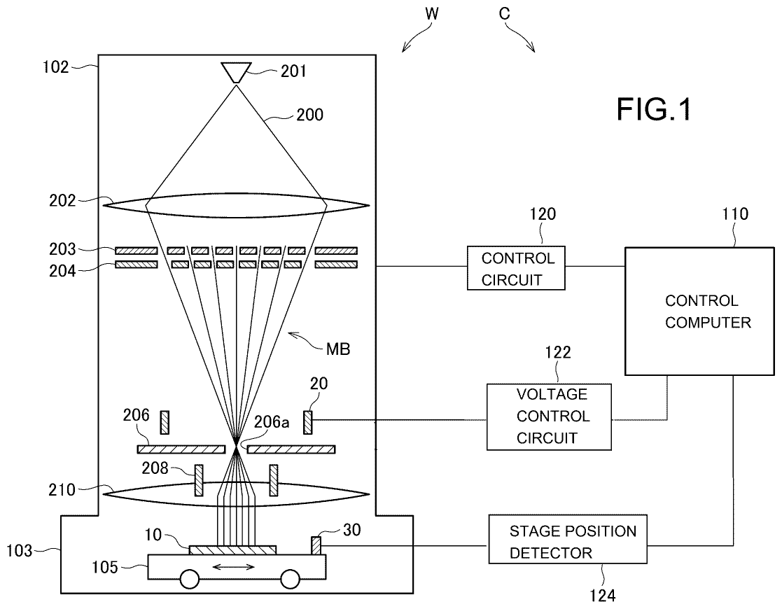

FIG. 1 is a schematic configuration view of a multi-beam writing apparatus according to an embodiment of the present invention. As illustrated in FIG. 1, a multi-beam writing apparatus includes a writer W and a controller C. The writer W includes an electron optical column 102 and a writing chamber 103. In the electron optical column 102, a charged particle source (electron source) 201, an illumination lens 202, a shaping aperture array substrate 203, a blanking aperture array substrate 204, an electrostatic deflector 20, a stopping aperture substrate 206, a positioning deflector 208, and an objective lens 210 are disposed which constitute an electron optical system of the multi-beam writing apparatus. The electrostatic deflector 20 is disposed in proximity to the stopping aperture substrate 206 between the blanking aperture array substrate 204 and the stopping aperture substrate 206.

In the writing chamber 103, an XY stage 105 movable in XY direction (a direction perpendicular to the central axis of the multi-beam trajectory) is disposed. The XY stage 105 may be movable in Z direction (the same direction as the central axis of the trajectory). On the XY stage 105, a substrate 10 as a writing target is disposed. The substrate 10 may refer to an exposure mask when a semiconductor device is fabricated, and a semiconductor substrate (silicon wafer) on which a semiconductor device is fabricated. In addition, the substrate 10 may refer to mask blanks coated with resist, on which nothing has been written.

On the XY stage 105, a mirror 30 for measuring the stage position is disposed.

The controller C includes a control computer 110, a control circuit 120, a voltage control circuit 122 and a stage position detector 124. The stage position detector 124 emits a laser, receives light reflected from the mirror 30, and detects the position of the XY stage 105 by the principle of laser interferometry.

FIG. 1 illustrates the components necessary for explaining the embodiment, and other components are not illustrated.

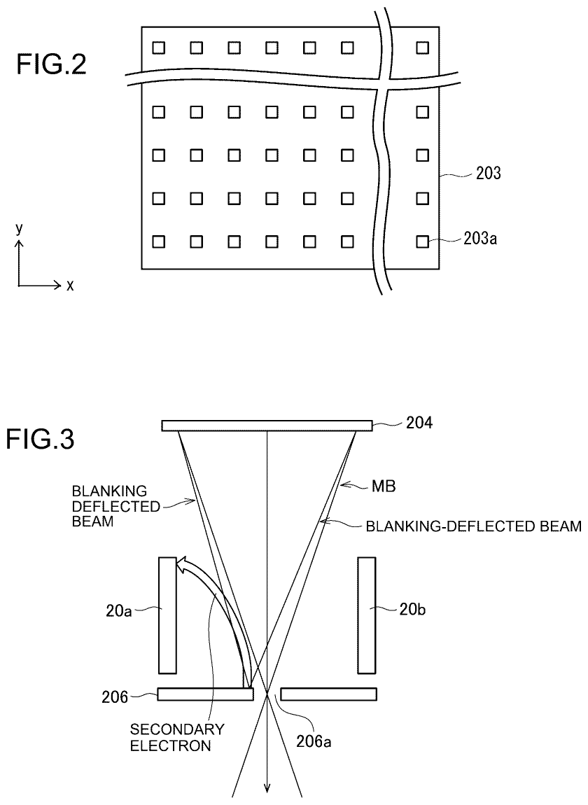

FIG. 2 is a conceptual view of the configuration of the shaping aperture array substrate 203. In the shaping aperture array substrate 203 of FIG. 2, openings (first openings) 203a in p vertical (y direction) columns×q horizontal (x direction) rows (p, q>=2) are formed in a matrix form with a predetermined arrangement pitch. For example, the openings 203a in 512 columns×512 rows are formed. The openings 203a are formed in rectangular shapes having the same dimensions. The openings 203a may be circular. Part of an electron beam 200 passes through a corresponding one of these multiple openings 203a, thereby forming a multi-beam MB.

The blanking aperture array substrate 204 is provided below the shaping aperture array substrate 203, and passage holes (second openings) are formed corresponding to the arranged positions of the openings 203a of the shaping aperture array substrate 203. Each passage hole is provided with a blanker consisting of a set of two paired electrodes. One electrode of the blanker is fixed to the ground electric potential, and the other electrode is switched between the ground electric potential (0V) and another electric potential. Electron beams passing through respective passage holes are each independently deflected by a voltage applied to a corresponding one of blankers. In this manner, multiple blankers perform blanking deflection on corresponding beams in the multi-beam MB which has passed through the multiple openings 203a of the shaping aperture array substrate 203.

The electron beam 200 emitted from the electron source 201 (emitter) is refracted by the illumination lens 202, and illuminates the entire shaping aperture array substrate 203. The electron beam 200 illuminates an area including the multiple (all) openings 203a. Part of the electron beam 200 passes through the multiple openings 203a of the shaping aperture array substrate 203, thereby forming a multi-beam MB including multiple individual beams. The multi-beam MB passes through corresponding blankers of the blanking aperture array substrate 204. The blankers each perform blanking control on a passing individual beam so that the beam is in ON state for a set writing time (irradiation time).

The multi-beam MB which has passed through the blanking aperture array substrate 204 forms a crossover by the focusing effect of the illumination lens 202. The stopping aperture substrate 206 is disposed so that an opening 206a (a third opening) formed in the center thereof has substantially the same height position as that of the crossover.

Each beam deflected by a blanker of the blanking aperture array substrate 204 deviates from the position of the opening 206a of the stopping aperture substrate 206, and is blocked by the stopping aperture substrate 206. In contrast, each beam not deflected by a blanker of the blanking aperture array substrate 204 passes through the opening 206a of the stopping aperture substrate 206. In this manner, the stopping aperture substrate 206 blocks the beams which have been deflected to achieve a beam OFF state by respective blankers.

In general, classification of apertures includes shaping aperture (including also “shaping aperture array”), limiting aperture (may be called “lens aperture”, or simply “aperture”), and stopping aperture. A shaping aperture is for shaping the beam to a desired shape, and disposed at a place where the beam is expanded by a lens system. The shaping aperture is irradiated with the beam, and allows only part of the beam, corresponding to the desired shape to pass through, and cuts off the remaining part of the beam. The lens aperture is for adjusting the beam current and the convergence state, and is disposed in the vicinity or at substantially the same position as the lens to allow the center of the spread beam to pass through and cut off unnecessary beam in the periphery. In contrast, the stopping aperture normally allows all beams to pass through, and cuts off only the beam on which blanking deflection has been performed. In an optical system for the multi-beam writing apparatus, the stopping aperture is disposed at a position near the height of the crossover where the beam spread is reduced.

In the embodiment of FIG. 1, the stopping aperture substrate 206 is arranged so that the height position of the opening 206a is substantially the same position as the height position of the crossover. Since the lateral spread of the beam is small at the crossover, this arrangement is suitable for cutting off the beam which is deflected to be in a beam-OFF state. If the height position of the crossover is vertically displaced from the height position of the opening 206a, the multi-beam MB is in a widely spread state at the height position of the opening 206a, and in addition, the electrodes of each blanker of the blanking aperture array substrate 204 have a microscopic structure, and are short, thus an applied voltage also has a limit, and it is difficult to increase the amount of deflection. Therefore, a problem of the writing function and the writing performance occurs, for example, a beam (part of individual beams) not sufficiently cut off at the time of beam cut-off is produced, or a beam (part of individual beams) continues to be cut off is produced.

The beam for one shot is formed by the beam which has passed through the stopping aperture substrate 206 since beam-ON until beam-OFF is achieved. Each beam in the multi-beam MB which has passed through the stopping aperture substrate 206 becomes an aperture image with a desired reduction ratio, of an opening 203a of the shaping aperture array substrate 203 by the objective lens 210, and is brought into focus on the substrate 10. The beams (the entire multi-beam) which have passed through the stopping aperture substrate 206 are collectively deflected by the positioning deflector 208 in the same direction, and are emitted to respective irradiation positions of the beams on the substrate 10.

For example, when the XY stage 105 is continuously moved, the irradiation position of each beam is controlled by the positioning deflector 208 so that the irradiation position follows the movement of the XY stage 105. The multi-beam MB emitted at once is ideally arranged with a pitch which is the product of the arrangement pitch of the multiple openings 203a of the shaping aperture array substrate 203 and the above-mentioned desired reduction ratio. The writing apparatus performs a writing operation by a raster scan method by which a shot beam is sequentially emitted continuously, and when a desired pattern is written, unnecessary beams are controlled at beam OFF by the blanking control.

In this writing apparatus, when the beam on which blanking deflection has been performed is cut off by the stopping aperture substrate 206, secondary electrons are emitted from the stopping aperture substrate 206, and the secondary electrons have an effect on the beam irradiation position. Note that since the hole diameter of the opening 206a of the stopping aperture substrate 206 is small (several 10 to several 100 μm), it is substantially impossible for the secondary electrons produced in a sample 10 to pass through the opening 206a, and reach upstream of the stopping aperture substrate 206 to have an effect on the beam irradiation position.

Thus, in the present embodiment, the electrostatic deflector 20 including a plurality of electrodes is disposed above (the front side in the beam traveling direction, upstream of the beam optical path) the stopping aperture substrate 206 and below the blanking aperture array substrate 204, and the voltage control circuit 122 applies a voltage to each electrode of the electrostatic deflector 20 so that an electric field is formed in a direction perpendicular to the trajectory central axis of the multi-beam. The voltage applied by the voltage control circuit 122, in other words, the voltage applied to each electrode of the electrostatic deflector 20 is constant (invariant) during a writing operation. The voltage applied to each electrode of the electrostatic deflector 20 is constant regardless of the change in the beam ON/OFF state.

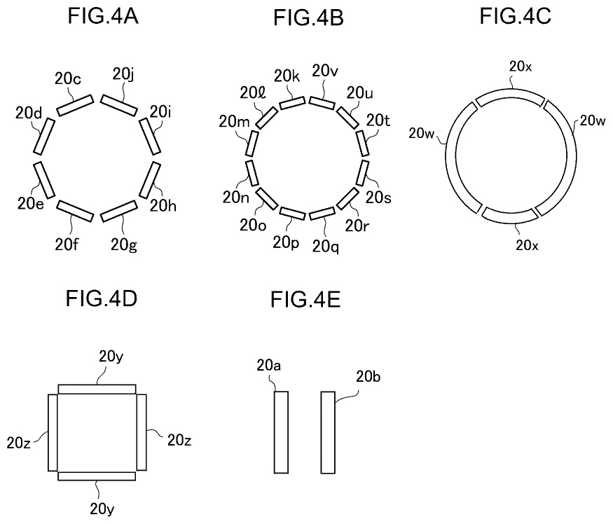

For example, when the electrostatic deflector 20 has two parallel-plate electrodes 20a and 20b as illustrated in FIGS. 3 and 4E, the voltage control circuit 122 applies a positive voltage to one electrode 20a, and applies a negative voltage to the other electrode 20b. The stopping aperture substrate 206 is set to the ground electric potential (0 V).

Consequently, an electric field is formed in the direction from the electrode 20b to the electrode 20a, thus secondary electrons emitted from the stopping aperture substrate 206 are deflected to the electrode 20a side, and collide with the wall surface of the electrode 20a, or are expelled in an outer direction slightly upstream of the electrode 20a. Since the secondary electron density in the vicinity of the trajectory of the multi-beam decreases, the effect of the secondary electrons on the beam can be reduced, and the beam irradiation position accuracy can be improved. Since the secondary electrons are deflected to the electrode 20a side by electric field control, the resulting effect has a small variation, and changes over time is also small.

When the distance between the electrostatic deflector 20 and the stopping aperture substrate 206 is large, the secondary electrons pass through the vicinity of the multi-beam trajectory over a long distance until they are deflected by the electric field of the electrostatic deflector 20, thus the effect on the multi-beam is not reduced sufficiently. Therefore, the electrostatic deflector 20 needs to be disposed in proximity to the stopping aperture substrate 206. Specifically, no other component is disposed between the electrostatic deflector 20 and the stopping aperture substrate 206 except for members for supporting those and members for electrical insulation. Normally, the downstream ends of the electrodes 20a and 20b of the electrostatic deflector 20 in the beam traveling direction are disposed within 20 mm from the stopping aperture substrate 206. In addition, a further significant effect is obtained by disposing the downstream ends within 10 mm.

When the focused magnetic field of an objective lens is exerted on the height position of the electrostatic deflector 20, the secondary electrons may move generally in the direction perpendicular to both the trajectory central axis direction and the deflection electric field direction, that is, the direction perpendicular to the paper surface in FIG. 3. In this case, the secondary electrons do not collide with the electrode 20a, but are expelled to the outside of the space between the electrodes, the secondary electron density in the vicinity of the trajectory of the multi-beam is reduced, and the beam irradiation position accuracy can be improved.

How much voltage is to be applied by the voltage control circuit 122 is determined based on the electrode length and electrode gap of the electrostatic deflector 20, and on the gap between the stopping aperture substrate 206 and the electrostatic deflector 20.

The material for the stopping aperture substrate 206 is not limited to a specific one, and e.g., Ta which is a non-magnetic material may be used. The shape of the stopping aperture substrate 206 and the opening 206a is e.g., circular.

The number of electrodes of the electrostatic deflector 20 is not limited. For example, the electrostatic deflector 20 may be an octupole type (also referred to as an “octupole electrostatic deflector”) having eight electrodes 20c to 20j as illustrated in FIG. 4A. The electrostatic deflector 20 may be a 12-pole type (also referred to as an “12-pole electrostatic deflector”) having 12 electrodes 20k to 20v as illustrated in FIG. 4B. In the octupole type, a positive voltage is applied to the electrodes 20c to 20f, and a negative voltage is applied to the electrodes 20g to 20j. In the 12-pole type, a positive voltage is applied to the electrodes 20k, 20m, 20n, 20p, a negative voltage is applied to the electrodes 20q, 20s, 20t, 20v, and the ground potential (0 V) is applied to the electrodes 20l, 20o, 20r, 20u. These electrostatic deflectors form an electric field in a direction perpendicular to the trajectory central axis of the multi-beam.

The electrostatic deflector 20 may be a quadrupole type (also referred to as a “quadrupole electrostatic deflector”) having four electrodes as illustrated in FIG. 4D. In the quadrupole type, positive and negative deflection voltages are applied to two opposed electrodes 20z, respectively, and 0 V is applied to the remaining two opposed electrodes 20y. Applying voltages in this manner forms an electric field in a direction perpendicular to the trajectory central axis of the multi-beam.

The above-described voltage application methods for the octupole, 12-pole, and quadrupole electrostatic deflectors is an example when the beam is to be deflected in a certain one direction (X direction). In contrast, when the beam is to be deflected in 90-degree direction (Y direction), a voltage should be applied in the same manner as described above to the electrodes disposed at a place after 90-degree rotation. When the beam is deflected in another direction (direction neither X direction nor Y direction), a voltage for X direction deflection and a voltage for Y direction deflection are added for each electrode, and applied thereto.

As in FIG. 4C, the electrostatic deflector 20 may have a configuration (also referred to as “120-degree electrode deflector”) achieved by two opposed electrodes 20w with a central angle of approximately 120 degrees, and the remaining two opposed electrodes 20x (with a central angle of approximately 60 degrees) out of four electrodes obtained by dividing a cylindrical surface centered on the trajectory central axis. Positive and negative deflection voltages are respectively applied to opposed electrodes 20w with a central angle of approximately 120 degrees, and 0 V is applied to the remaining two opposed electrodes 20x. Applying voltages in this manner forms an electric field in a direction perpendicular to the trajectory central axis of the multi-beam.

The deflection electric field formed by the electrostatic deflector 20 also has an effect on the multi-beam MB utilized for writing. The electrostatic deflector 20 is disposed at a place where the multi-beam MB upstream of the stopping aperture substrate 206 is slightly spread, thus when the non-uniformity of deflection electric field is high (in other words, when the uniformity of deflection electric field is low), the deflection electric field varies for each individual beam, and array distortion (displacement from a normal irradiation position) on a sample surface increases, thus the beam accuracy deteriorates.

Reduction in array distortion is a new problem to be addressed in a multi-beam optical system. The multi-beam optical system forms an array beam, for example, on a sample surface, the array beam with extremely large dimensions of approximately 100 μm in length and width, thus unlike a conventional variable shaped beam optical system that forms a small beam with approximately 1 μm or less, the array distortion is likely to increase, and it is significantly important to reduce the increase in the array distortion. When increase in the array distortion is reduced by decreasing the non-uniformity of the deflection electric field formed by the electrostatic deflector 20, the beam accuracy can be further improved. In other words, in the design of the electrostatic deflector 20, it is also important to achieve not only the formation of an electric field that simply attracts secondary electrons, but also the formation deflection electric field with low non-uniformity (in other words, high uniformity).

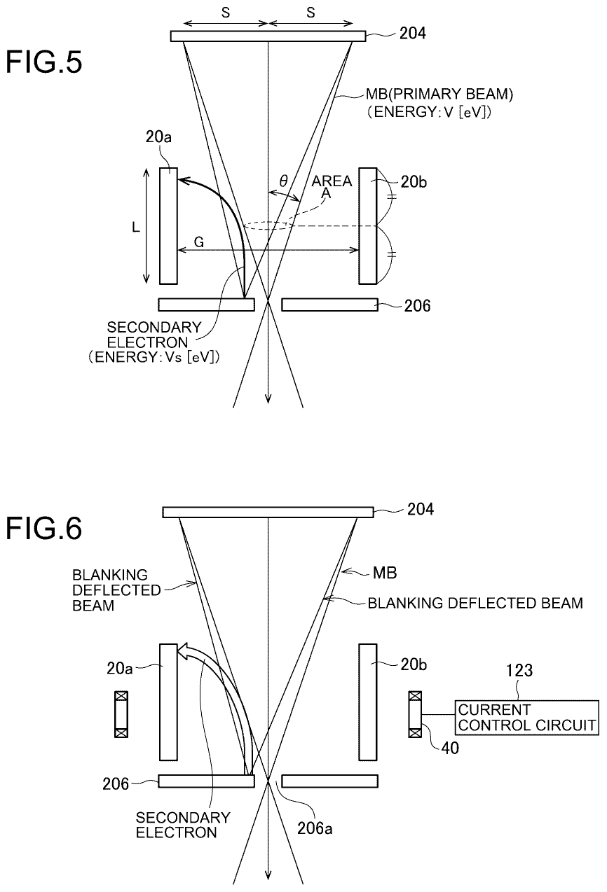

The increase in the array distortion can be associated with the electric field non-uniformity of the electrostatic deflector 20, and the parameters (basic elements) of the optical system and the electrostatic deflector 20. As illustrated in FIG. 5, as the parameters, an electrostatic deflector electrode length L, an electrostatic deflector electrode gap G, a secondary electron energy representative value V_{S} (unit eV), a primary beam energy V (unit eV), a shaping aperture array radius S, and a crossover convergence half-angle θ (unit rad) are introduced. In addition, let M be imaging magnification, and D be distortion increase. Let η be electric field non-uniformity. Let D_{MAX} be distortion increase upper limit.

The electrostatic deflector electrode length L is the length of electrodes in the trajectory central axis direction, the electrodes being included in the electrostatic deflector 20. The electrostatic deflector electrode gap G is the gap between the opposed electrodes of the electrostatic deflector 20, or the diameter of a circle in contact with the inner surfaces of the electrodes included in the electrostatic deflector 20 centered on the trajectory central axis.

In general, the energy of secondary electron has a distribution. Let V_{S} be the representative value of the energy of the secondary electrons which are produced in the stopping aperture substrate 206, and move upstream. Normally, the material for the stopping aperture substrate 206 is metal, thus the energy of most secondary electrons is distributed in a range less than or equal to 20 eV, and has a peak in the distribution near 2 eV. Therefore, normally V_{S} may be 2 eV. The primary beam energy V is the acceleration energy of the primary beam (that is, the multi-beam MB).

The shaping aperture array radius S is the distance from the trajectory central axis to the opening which is the farthest (in other words, the outermost) from the trajectory central axis among the openings 203a formed in the shaping aperture array substrate. When the opening 203a is arranged on a rectangular area centered on the trajectory central axis, S is half the length of the diagonal of the arrangement area.

The crossover convergence half-angle θ is the convergence half-angle of the multi-beam MB to the crossover. The imaging magnification M is the magnification when the plurality of openings 203a of the shaping aperture array substrate 203 are projected on the sample surface.

The distortion increase D is distortion of the sample surface caused by the electric field non-uniformity, and is added to the optical system distortion (in other words, the original distortion of an optical system) to increase the distortion. The distortion increase upper limit D_{MAX} is the upper limit value of D, and set in consideration of the performance required for the apparatus. D_{MAX} needs to be set to substantially equal to or less than the optical system distortion, and is normally set to ⅓ the optical system distortion. For example, when the optical system distortion is 6 nm (6×10⁶⁻⁹ m), D_{MAX} is set to 2 nm.

The electric field non-uniformity η is a maximum value of the quotient obtained by dividing the absolute value of the difference (|E₁−E₀|) between a deflection electric field E₁ and an electric field E₀ in the center of an area A by the absolute value (|E₀|) of E₀ in the area A, through which the multi-beam passes, within a plane perpendicular to the trajectory central axis, near the center of the electrostatic deflector 20 in the trajectory central axis direction (in other words, near the center of the upper and lower ends). In other words, the difference (non-uniform component of the electric field) between the electric field E₁ in the area A and the electric field E₀ in the center of the area A, through which the multi-beam passes is calculated, the quotient obtained by dividing the absolute value of the difference by the absolute value of the central electric field (reference electric field) is determined, and the maximum value of the quotient in the area A gives the electric field non-uniformity η. Note that the area A is as schematically illustrated in FIG. 5. Because the electric fields E₁, E₀ are vector quantities, calculation of difference, and absolute value follows the method of vector calculation. The multi-beam MB is most spread near the upper end (near the entrance) of the electrostatic deflector 20, and is reduced as the multi-beam MB moves. As described above, when the electric field non-uniformity η is the value calculated for the vicinity of the center of electrostatic deflector 20 in the trajectory central axis direction, the value can represent the non-uniformity over the entire length of the electrostatic deflector 20. Note that the area A can be determined by electron beam trajectory calculation, and the electric fields E₁, E₀ can be determined by electric field calculation.

When the electric field non-uniformity η is given, the sample surface distortion increase D can be calculated by the following Expression.

$$D = η ( G / L ) \times ( {V}_{S} / V ) \times ( S / θ ) \times M \qquad ( 1 )$$

As in FIG. 5, it is assumed that the multi-beam MB is blanked, collides with the stopping aperture substrate 206 to produce secondary electrons, and the secondary electrons are bent by the electric field of the electrostatic deflector 20 while moving upstream, and reach the vicinity of the upper end of the electrostatic deflector electrode 20a. The surface of the deflection electrode 20a is very far from the trajectory central axis than from the position at which the multi-beam MB collides with the stopping aperture substrate 206, thus the deflection angle of the secondary electrons in this situation can be approximated by G/L which is the quotient obtained by dividing the distance G/2 from the trajectory central axis to the deflection electrode surface by the length L/2 of the deflection electrode. Therefore, (G/L) in Expression (1) corresponds to the deflection angle of the secondary electrons.

The deflection angle of the primary beam (energy V) which passes through, in an opposite direction, an electric field in which the secondary electrons (energy V_{S}) are deflected is (V_{S}/V) times the deflection angle of the secondary electrons. This is because the angle (deflection angle) by which electrons are bent due to the deflection electric field is inversely proportional to the electronic energy. Therefore, (V_{S}/V) in Expression (1) corresponds to the coefficient for converting the deflection angle of the secondary electrons into the deflection angle of the primary beam (that is, the multi-beam MB).

S corresponds to the radius of the outermost beam on the stopping aperture substrate 206, and θ corresponds to the incident angle of the outermost beam to the crossover. Therefore, (S/θ) in Expression (1) corresponds to the coefficient for converting the deflection angle (in other words, the amount of change in angle) of the trajectory near the stopping aperture substrate 206 into an imaginary amount of movement of the opening 203a of the shaping aperture array substrate 203. The imaginary amount of movement is increased to M times by the lens system, projected on the sample surface, and becomes the amount of movement of the projection position. M in Expression (1) is the coefficient for converting the imaginary amount of movement of the opening 203a of the shaping aperture array substrate 203 into the amount of movement of the projection position.

When the deflection electric field is ideally formed uniformly, the amount of movement of the projection position on the above sample surface is constant over the entire array, and the array image is translated with its shape maintained. However, when non-uniformity is present in the deflection electric field, the deflection electric field varies for each individual beam, and the distortion of the array shape on the sample surface increases. In Expression (1), multiplication by the non-uniformity η of the deflection electric field calculates the increase D of the array distortion.

In Expression (1), D is replaced by the upper limit D_{MAX} of the sample surface distortion increase, and solving for η gives the following Expression that gives the upper limit of the electric field non-uniformity η.

$$η \leq {D}_{MAX} / \{ ( G / L ) \times ( {V}_{S} / V ) \times ( S / θ ) \times M \} \qquad ( 2 )$$

For example, in an optical system in which the electrostatic deflector electrode length L=50 mm, the electrostatic deflector electrode gap G=20 mm, the secondary electron energy representative value V_{S}=2 eV, the primary beam energy V=50 keV, the shaping aperture array radius S=10 mm, the crossover convergence half-angle θ=20 mrad, and the imaging magnification M=1/200, when the distortion increase upper limit D_{MAX}=2 nm, it is calculated that the electric field non-uniformity η needs to be less than or equal to 5% (0.05).

As the electrostatic deflector 20, it is desirable to use a deflector that meets the electric field non-uniformity condition in Expression (2). When Expression (2) is met, the secondary electron density in the vicinity of the multi-beam trajectory can be reduced while preventing increase in the array distortion, and the beam irradiation position accuracy can be further improved.

In general, deflection electric field generated by a deflector can be calculated based on the electrode shape and the like, and the non-uniformity of the electric field can be determined from the result of the calculation. The non-uniformity of the electric field can be reduced by optimizing the electrode shape and the like. Note that the electrode shape and the like include the number of electrodes, the electrode gap (or diameter), the electrode length, the shape of each electrode, and the method of applying a voltage to each electrode.

The octupole electrostatic deflector (FIG. 4A), the 12-pole electrostatic deflector (FIG. 4B), and the 120-degree electrode deflector (FIG. 4C) have the characteristic that the uniformity of the deflection electric field is extremely high, and are more advantageous than the quadrupole electrostatic deflector (FIG. 4D) and the parallel-plate electrostatic deflector (FIG. 4E) from the viewpoint of reduction of the distortion caused by electric field non-uniformity.

In the quadrupole electrostatic deflector (FIG. 4D), when the gap (the gap between the electrodes 20y, 20y, the gap between the electrodes 20z, 20z) between opposed electrodes is sufficiently widened, the uniformity of the area through which the beam passes can be increased. For example, in order to reduce the electrode non-uniformity to 5% or less, the electrode gap of the quadrupole electrostatic deflector should be greater than or equal to 4.2 times the diameter of the area A through which the multi-beam MB passes.

In the parallel-plate electrostatic deflector (FIG. 4E), the electrode gap is made sufficiently larger than the spread of the passing beam, and the electrode width (the dimension of the surface facing the beam, in a direction perpendicular to the beam traveling direction) is made greater than or equal to the electrode gap, thus the uniformity of the area through which the beam passes can be increased. For example, in order to reduce the electric field non-uniformity to 5% or less, the electrode gap should be greater than or equal to 2.5 times the diameter of the area A through which the multi-beam MB passes, and the electrode width should be greater than or equal to the electrode gap.

In the above embodiment, an example has been described in which the stopping aperture substrate 206 is set to the ground electric potential; however, the voltage control circuit 122 may apply a negative voltage to the stopping aperture substrate 206. The negative voltage of the stopping aperture substrate 206 causes the secondary electrons to be accelerated in an upstream direction, and the spatial density is decreased, thus the effect on the multi-beam MB is reduced. With the effect on the multi-beam MB reduced, the secondary electrons are moved to be separated from the vicinity of the trajectory of the multi-beam MB by the electric field of the electrostatic deflector 20, thus the beam irradiation position accuracy can be further improved.

The voltage control circuit 122 may apply a positive voltage to the stopping aperture substrate 206. The positive voltage of the stopping aperture substrate 206 causes the secondary electrons to be pulled back, and the secondary electrons moving upstream are decreased, thus the effect on the multi-beam MB is reduced. With the effect on the multi-beam MB reduced, the secondary electrons which have moved upstream are moved to be separated from the vicinity of the trajectory of the multi-beam MB by the electric field of the electrostatic deflector 20, thus the beam irradiation position accuracy can be further improved.

The voltage control circuit 122 may set the stopping aperture substrate 206 to the ground electric potential, and may apply the sum of a voltage for forming an electric field in a direction perpendicular to the trajectory central axis and a positive common voltage to each electrode of the electrostatic deflector 20. For example, when the electrostatic deflector 20 is a quadrupole type illustrated in FIG. 4D, positive and negative deflection voltages and a common voltage are added up and applied to two opposed electrodes 20z, and the sum of 0 V and a common voltage is applied to the remaining two opposed electrodes 20y. The positive common voltage causes the secondary electrons to be accelerated in an upstream direction, and the spatial density is decreased, thus the effect on the multi-beam MB is reduced. With the effect on the multi-beam MB reduced, the secondary electrons are moved to be separated from the vicinity of the trajectory of the multi-beam MB by a component (deflection electric field component) of the electric field of the electrostatic deflector 20, the component being perpendicular to the trajectory central axis, thus the beam irradiation position accuracy can be further improved.

The voltage control circuit 122 may set the stopping aperture substrate 206 to the ground electric potential, and may apply the sum of a voltage for forming an electric field in a direction perpendicular to the trajectory central axis and a negative common voltage to each electrode of the electrostatic deflector 20. The negative common voltage causes the secondary electrons to be pulled back, and the secondary electrons moving upstream are decreased, thus the effect on the multi-beam MB is reduced. With the effect on the multi-beam MB reduced, the secondary electrons which have moved upstream are moved to be separated from the vicinity of the trajectory of the multi-beam MB by a component (deflection electric field component) of the electric field of the electrostatic deflector 20, the component being perpendicular to the trajectory central axis, thus the beam irradiation position accuracy can be further improved.

As illustrated in FIG. 6, on the plane perpendicular to the trajectory central axis of the multi-beam MB, it is preferable to provide a magnetic field deflector 40 that generates a magnetic field in a direction perpendicular to the electric field formed by the electrostatic deflector 20, and a current control circuit 123 that controls the current which flows through the magnetic field deflector 40. For the multi-beam MB which has passed through the blanking aperture array substrate 204, a force due to the electric field and a force due to the magnetic field cancel each other, thus the multi-beam MB moves straight downward without being deflected. In contrast, on the secondary electrons emitted from the stopping aperture substrate 206, a force due to the electric field and a force due to the magnetic field are exerted in the same direction, and the secondary electrons are bent to the positive-voltage-applied electrode side of the electrostatic deflector 20.

In a configuration in which the magnetic field deflector 40 is not disposed, the multi-beam MB is deflected by the electrostatic deflector 20, and is obliquely incident on a position slightly deviated from the center of the objective lens 210 downstream of the blanking aperture array substrate 204, thus the aberration and distortion on the sample surface in the imaging of the objective lens 210 may be increased. However, due to installation of the magnetic field deflector 40, the multi-beam MB moves straight downward because the deflection effect is cancelled, thus the aberration and distortion on the sample surface caused under the presence of deflection are reduced, and the writing accuracy can be further improved. Note that as described above, the aberration and distortion reduced by installation of the magnetic field deflector 40 are caused by oblique incidence and off-center of the beam on the objective lens 210, and are different from the distortion caused by the electric field non-uniformity of the electrostatic deflector 20.

It is sufficient that the magnetic field deflector 40 can generate a magnetic field that reverses part or all of the deflection of the multi-beam MB caused by the electric field of the electrostatic deflector 20 to reduce the oblique incidence and off-center of the beam on the objective lens 210. Therefore, the magnetic field generated by the magnetic field deflector 40 and the electric field generated by the electrostatic deflector 20 do not need to be completely perpendicular to each other at all positions, and should have opposite directions in which the multi-beam MB is deflected. In addition, the magnetic field deflector 40 may be disposed at a position deviated from the electrostatic deflector 20 in the trajectory central axis direction, or may have multiple stages.

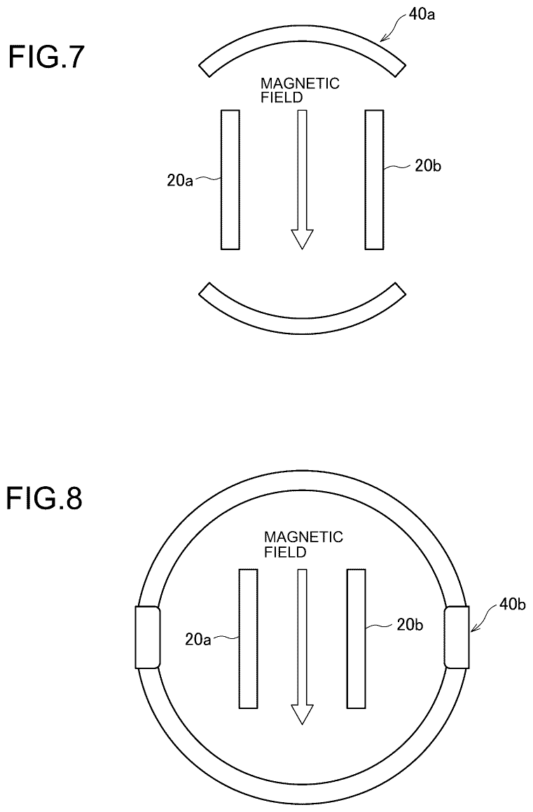

The magnetic field deflector 40 includes a plurality of coils, and generates a magnetic field which has the effect of deflecting the beam by passing a current through the coils. For example, a saddle coil 40a as illustrated in FIG. 7, and a toroidal coil 40b as illustrated in FIG. 8 may be used. The magnetic field deflector 40 may be an octupole type having eight coils, or a 12-pole type having 12 coils.

In order to reduce the increase in the distortion also in a magnetic field deflector, as in an electrostatic deflector, uniformity of the deflection magnetic field in the periphery of the trajectory central axis is required. In order to obtain sufficient uniformity, the distribution of generated deflection magnetic field is calculated based on the shape of the coils and peripheral magnetic materials, and the shape should be optimized so as to ensure the uniformity of the magnetic field. A magnetic field deflector is normally disposed outside vacuum, thus has a larger diameter than that of an electrostatic deflector, therefore uniformity of the magnetic field in the periphery of the trajectory central axis is relatively high. Particularly, in the saddle coil 40a illustrated in FIG. 7, when the angle of circumferential view of the coil from the central axis is approximately 120 degrees, uniformity of the deflection magnetic field is high and advantageous. When the magnetic field deflector is an octupole type having eight coils, or a 12-pole type having 12 coils, even if a saddle coil is used or a toroidal coil is used, it is easy to increase the uniformity of the deflection magnetic field.

In addition, it is preferable to use a configuration in which one (or both) of the electrostatic deflector and the magnetic field deflector is a deflector with four or more poles, and the deflection direction (direction around the trajectory central axis) is controllable. Only with mechanical manufacturing accuracy, it is difficult to achieve accurately opposite deflection directions of the electric field due to the electrostatic deflector and the magnetic field due to the magnetic field deflector. However, when either one deflector is set to a deflector with four or more poles, and the direction of the electric field or the magnetic field is made controllable, the deflection directions can be set to opposite directions with high accuracy.

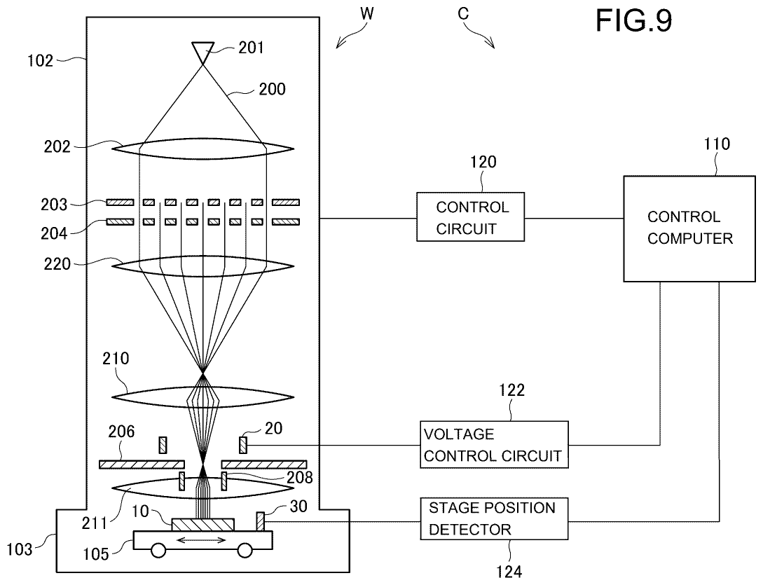

The above-described embodiment of FIG. 1 has a configuration in which the objective lens is a single-stage lens, and the stopping aperture substrate 206 is disposed at the position of the crossover formed between the blanking aperture array substrate 204 and the objective lens 210; however, as illustrated in FIG. 9, a configuration may be adopted in which a reduction lens 220 and two-stage objective lenses 210, 211 are provided, and the stopping aperture substrate 206 is disposed at the position of the crossover formed downstream of the upstream objective lens 210.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam irradiation apparatus comprising:
a charged particle source that emits a charged particle beam;
a shaping aperture array substrate having a plurality of openings through which the charged particle beam passes to form a multi-beam;
a blanking aperture array substrate having a plurality of blankers that perform blanking deflection on each beam of the multi-beam;
an illumination lens that forms a crossover by focusing the multi-beam which passes through the blanking aperture array substrate;
a stopping aperture substrate disposed at a position of the crossover and configured to block a beam which is deflected to be in a beam-OFF state by the plurality of blankers;
a stage on which a substrate to be irradiated with a beam passing through the stopping aperture substrate is placed;
an electrostatic deflector disposed in proximity to the stopping aperture substrate, between the blanking aperture array substrate and the stopping aperture substrate; and
a voltage control circuit configured to form an electric field perpendicular to a trajectory central axis of the multi-beam by applying a predetermined voltage to the electrostatic deflector.

2. The multi-charged particle beam irradiation apparatus according to claim 1,
wherein no other component is disposed between the stopping aperture substrate and the electrostatic deflector.

3. The multi-charged particle beam irradiation apparatus according to claim 1,
wherein a constant voltage is applied to the electrostatic deflector.

4. The multi-charged particle beam irradiation apparatus according to claim 1,
wherein the electrostatic deflector has four or more electrodes.

5. The multi-charged particle beam irradiation apparatus according to claim 4,
wherein the electrostatic deflector is an octupole electrostatic deflector, a 12-pole electrostatic deflector, or a 120-degree electrode deflector.

6. The multi-charged particle beam irradiation apparatus according to claim 4,
wherein a downstream end of the electrode in a multi-beam traveling direction is disposed within 20 mm from the stopping aperture substrate.

7. The multi-charged particle beam irradiation apparatus according to claim 1,
wherein an electric field non-uniformity η is defined as a maximum value of a quotient obtained by dividing an absolute value of a difference between an electric field E₁ in a region through which the multi-beam passes within a plane perpendicular to a trajectory central axis at a center of the electrostatic deflector in a direction of the trajectory central axis, and an electric field E₀ on the trajectory central axis in the region, by an absolute value of the electric field E₀, and an upper limit of the electric field non-uniformity η satisfies
$$η \leq {D}_{MAX} / \{ ( G / L ) \times ( {V}_{S} / V ) \times ( S / θ ) \times M \} ,$$
where D_{MAX} is an upper limit of distortion increase on a substrate surface, L is an electrode length of the electrostatic deflector, G is an electrode gap of the electrostatic deflector, V_{S} is a representative value of secondary electron energy, V is a primary beam energy, S is a shaping aperture array radius, θ is a crossover convergence half-angle, and M is an imaging magnification.

8. The multi-charged particle beam irradiation apparatus according to claim 7,
wherein the upper limit D_{MAX} of the distortion increase is set to one-third of an optical system distortion.

9. The multi-charged particle beam irradiation apparatus according to claim 1, further comprising
a magnetic field deflector that generates a magnetic field in which a deflection direction is opposite to a direction in which the multi-beam is deflected by the electric field.

10. The multi-charged particle beam irradiation apparatus according to claim 9,
wherein the deflection direction caused by the magnetic field is controllable.

11. The multi-charged particle beam irradiation apparatus according to claim 9,
wherein at least one of the electrostatic deflector and the magnetic field deflector has four or more electrodes or a coil.

12. The multi-charged particle beam irradiation apparatus according to claim 1,
wherein the voltage control circuit applies a positive or negative voltage to the stopping aperture substrate.

13. The multi-charged particle beam irradiation apparatus according to claim 1,
wherein the electrostatic deflector has a plurality of electrodes, and a voltage with a positive or negative common voltage added is applied to each of the plurality of electrodes.

14. A multi-charged particle beam irradiation method comprising:
a step of emitting a charged particle beam using a charged particle source;
a step of forming a multi-beam by letting the charged particle beam pass through a plurality of openings provided in a shaping aperture array substrate;
a step of performing blanking deflection on each beam in the multi-beam using a blanking aperture array substrate including a plurality of blankers;
a step of forming a crossover by focusing the multi-beam which passes through the blanking aperture array substrate;
a step of blocking a beam, which has been deflected to a beam-OFF state by the blanking aperture array substrate, by a stopping aperture substrate disposed at a position of the crossover;
a step of irradiating a predetermined position of a substrate placed on a stage with a beam which has passed through the stopping aperture substrate; and
a step of forming an electric field in a direction perpendicular to a trajectory central axis of the multi-beam by applying a predetermined voltage to an electrostatic deflector disposed between the blanking aperture array substrate and the stopping aperture substrate and in proximity to the stopping aperture substrate.

15. The multi-charged particle beam irradiation method according to claim 14,
wherein a constant voltage is applied to the electrostatic deflector.

16. The multi-charged particle beam irradiation method according to claim 14,
wherein an electric field non-uniformity η is defined as a maximum value of a quotient obtained by dividing an absolute value of a difference between an electric field E₁ in a region through which the multi-beam passes within a plane perpendicular to a trajectory central axis at a center of the electrostatic deflector in a direction of the trajectory central axis, and an electric field E₀ on the trajectory central axis in the region, by an absolute value of the electric field E₀, and an upper limit of the electric field non-uniformity η satisfies
$$η \leq {D}_{MAX} / \{ ( G / L ) \times ( {V}_{S} / V ) \times ( S / θ ) \times M \} ,$$
where D_{MAX} is an upper limit of distortion increase on a substrate surface, L is an electrode length of the electrostatic deflector, G is an electrode gap of the electrostatic deflector, V_{S} is a representative value of secondary electron energy, V is a primary beam energy, S is a shaping aperture array radius, θ is a crossover convergence half-angle, and M is an imaging magnification.

17. The multi-charged particle beam irradiation method according to claim 16,
wherein the upper limit D_{MAX} of the distortion increase is set to one-third of an optical system distortion.

18. The multi-charged particle beam irradiation method according to claim 14, further comprising a step of generating, by using a magnetic field deflector, a magnetic field in which a deflection direction is opposite to a direction in which the multi-beam is deflected by the electric field.

19. The multi-charged particle beam irradiation method according to claim 14,
wherein a positive or negative voltage is applied to the stopping aperture substrate.

20. The multi-charged particle beam irradiation method according to claim 14,
wherein a voltage with a positive or negative common voltage added is applied to each of a plurality of electrodes included in the electrostatic deflector.
